(19) United States
(12) Patent Application Publication
(10) Pub. No.: US 2012/0125766 A1
(43) Pub. Date: May 24, 2012

(54) Magnetron with non-equipotential cathode

(76) Inventors: Viacheslav V. Zhurin, (US); Nikolay G. Elistratov, Moscow (RU); Petr A. Tsygankov, Moscow (RU)

(21) Appl. No.: 12/927,685

(22) Filed: Nov. 22, 2010

(51) Int. Cl. C23C 14/35; H05K 13/00

(52) U.S. Cl. 204/298.12; 29/602.1

(57) ABSTRACT

In accordance with one embodiment of the present invention, a Magnetron Sputtering System consists of a Non-Equipotential Cathode with two or more group of segments made of one or different materials. Each group of segments is electrically insulated from others. At group or groups of segments called as Low-Voltage there is maintained a self-established electric voltage relating to anode that is less than voltages are maintained at remained cathode-target groups of segments called as High-Voltage. Such a Magnetron Sputtering System with a Non-Equipotential cathode makes possible to regulate energy of ions bombarding the cathode parts to control and substantially increase a local productivity of a Magnetron Sputtering System without increasing a discharge current and without change of magnetic field and pressure. Existing Magnetron Sputtering Systems can be adapted for application with this method.

### FIELD OF INVENTION

This invention relates in general to a technology of magnetron sputtering systems that can be utilized in a thin film deposition for large varieties of technical needs, such as corrosion resistance, protective, decorative and hard-coatings, production conductive and non-conductive films in semiconductor applications, deposition of super-thin protective coatings on heads and magnetic disks, production of diamond-like coatings in various industries, for design of optics filters etc.

### BACKGROUND ART

For the first time magnetron sputtering utilizing a direct current (DC) as a technological method was suggested by F. M. Penning in U.S. Pat. No. 2,146,025 “Coating by Cathode Disintegration”, Feb. 7 1939. In comparison with a cathode sputtering in a glow discharge, in a magnetron sputtering system (MSS), frequently called as a magnetron, there is realized a gas discharge in crossed electric and magnetic fields, in which there are formed conditions for more intensive sputtering of a cathode-target. For this purpose, an external magnetic field is selected in to provide magnetization of electron component near cathode that developed conditions for intensive ionization of a plasma developing working gas. “Magnetized” plasma means that plasma components experience many revolutions around magnetic field line before they move due to a collision with a neighbor particle. In general, only one plasma component is magnetized, especially, that only electrons are magnetized and ions are not magnetized. In this case, a developed plasma concentration is sufficient for obtaining a substantial ion current to a cathode that can achieve several units of Amperes per square centimeter. It is important to note that in a magnetron a potential drop is concentrated in a narrow near-cathode layer, where a current transfer is realized mainly by ions as this physical process was described by M. J. Goeckner, J. A. Goree, T. E. Sheridan, Jr., “Monte Carlo Simulation of Ions in a Magnetron Plasma”, IEEE Trans on Plasma Science, vol. 19, No. 2, 1991. Ions accelerated in a near-cathode layer arrive to a cathode-target with energy sufficient for its effective sputtering. Sputtered atoms of a cathode-target material are deposited on a substrate surface placed near magnetron developing a thin film with composition corresponding to or close to a cathode-target composition.

The Penning's magnetron was operated on a direct current and had a cylindrical geometry with a coaxial cathode and anode. A U.S. Pat. No. 3,616,450 “Sputtering Apparatus” by P. J. Clark in 1971 helped to intensive commercial utilization of DC-magnetrons of cylindrical-coaxial geometry for deposition of thin films, and, especially, for integrated circuits (IC) industry. History of development of a coaxial (axial-symmetrical) MSS configuration was described in detail in J. A. Thornton, “Thin Film Processes”, ed. by J. L. Vossen and W. Kern, Academic Press, New York, 1978.

Later in a U.S. Pat. No. 3,878,085 “Cathode Sputtering Apparatus”, by J. F. Corbani, July 1973 and in a U.S. Pat. No. 4,166,018,“Sputtering Process and Apparatus”, by J. S. Chapin, August 1979 there was suggested design of a so-called planar magnetron with a plane cathode-target, at which vicinity there is formed a magnetic field of arch configuration determining a space area, in which there is developed a magnetron discharge with a closed azimuthal drift of magnetized electrons. In this case, a necessary configuration can be created both by a magnetic system and a profiled cathode-target using, as a rule, conical profiled or convex targets. In such a sputtering system a vacuum chamber very frequently utilized as anode. Sometime anode is made in a form of a separate electrode placed over perimeter of a cathode-target under a ground potential of a vacuum chamber, or under a small bias of not more than 150 V. At present time, a similar scheme of formation of a magnetron discharge is utilized in majority of operating MSS with plane rectangular, cylindrical and profiled cathodes-targets.

Utilization of magnetic field of special configuration is effective way for control of a gas discharge in MSS. In work “The Unbalanced Magnetron: Current Status of Development” by W. D. Munz, Surface and Coating Technology, Volume 48, Issue 1, October 1991, p 81-94, there was considered schematic of so-called “unbalanced magnetron”, in which due to formation of special configurations of a space distributed magnetic field there is achieved a motion of discharge electrons from cathode into a required direction. Such schematic makes possible either to decrease a plasma concentration near a substrate with a purpose of regulation of electron or ion impact on deposition during process of its formation. This idea was then developed further by D. G. Teer in a U.S. Pat. No. 5,556,519 “Magnetron Sputter Ion Plating”, March 1994, where there was suggested to utilize two, or more unbalanced magnetrons, which magnetic fields configurations are connected with each other, making possible development of a closed-field magnetron sputtering near substrate operating as a trap for electrons effectively modifying process of a thin film deposition. It is important to note that above described modifications of magnetic field configurations do not change basics of a MSS operation on a dc current suggested by Penning.

Considered MSS, as it was above noted, operates with a DC current. During sputtering of metal (electrically conducting) and semiconducting targets as working gases there are utilized noble gases, as a rule. For example, Argon has a working pressure of 0.05-5.0 Pa. For formation of dielectric depositions or films with poor electric conductivity there is utilized a magnetron target sputtering in a media of reactive gases such as Nitrogen and Oxygen. However, utilization of reactive gases leads to development on a cathode-target surface of local oxidized non-conducting depositions, which become charged to high electric potentials sufficient for electric breakdown of these dielectric films. Micro-breakdowns disturb a magnetron stable operation and induce development of small arc discharges. In order to overcome this shortcoming, beginning of 1990ies, in industry there were introduced DC Pulsed MSS as it was described by S. Schiller, K. Goedicke et al., “Pulsed Magnetron Sputter Technology”, Surface Coating Technology, 1993, v. 61, p. 331-337. In contrast with DC magnetrons, an electric potential on a cathode-target in a pulsed MSS is applied in a form of unipolar (so-called DC-pulsed magnetrons), or bipolar pulses following with frequency from 2 to 100 kHz and with duration sufficient for development of established magnetron discharge, but insufficient for accumulation of electric charge and development of micro-breakdowns on oxidized surface of a cathode-target, providing necessary protection from development of arcs. Usually scheme of a pulsed power supply presents itself a standard scheme of a power supply with a DC current and additional electronic switch that modulates a DC supply with necessary on-off time ratio.

One of versions of DC-pulsed magnetron systems utilized in industry is a dual pulsed MSS consisting of two similar magnetrons and having independent, or mutually dependent magnetic systems, on which there are applied alternatively the symmetrical pulses of different polarity, in result, the targets alternatively perform a role of cathode and anode. Such system effectively solves the MSS stable operation problems in a media of reactive gases, and, besides that, makes possible to avoid development on anode of the non-conducting films leading to “anode loss”. In this case, a power supply for such configuration can be realized from a source of alternating current of low frequency of 50-10000 Hz, as it was suggested in a patent DE 3802853 A1 of 01.01.1988 by W. D. Munz, or by utilization of symmetrical rectangular bipolar voltage pulses with frequency higher than 10 kHz, as it was described in work by S. Schiller, K. Goedicke et al., “Pulsed Magnetron Sputter Technology”, Surface Coating Technology, 1993, v. 61, p. 331-337, and in a short review by S. Schiller, V. Kirchhoff, K. Gedicke, N. Schiller, “Pulsed Plasma—a New Era of PVD-Technique.”, Dresden, Germany. “FEP Annual Report”, 1996, p. 23-30.

In principle, physics of discharge in DC-pulsed MSS, in which during a pulse of negative potential there is formed established magnetron discharge, is similar to a magnetron discharge with a DC current, and established pulsed discharge voltages are close to voltages of DC magnetrons. Further in text, a Magnetron Sputtering System will be considered as magnetron of a coaxial or planar geometry operating either in a DC current, or in a pulsed (unipolar, or bipolar) regime, in which there is developed an established magnetron discharge. A magnetic field configuration in such magnetron can be both a balanced and unbalanced.

Discharge voltages and currents are interconnected parameters in a magnetron sputtering system. Relationships between currents and voltages in a MSS determined by the Volt-Ampere Characteristics (VAC) depend, in general, on a cathode material, composition and pressure of plasma developing gas media, and also on magnetic induction and its configuration over a target's surface. For most cathode materials and plasma developing media the discharge voltages are from 200 V to 700 V, as described by J. Reece Roth “Industrial Plasma Engineering”, v. 2, IOP Publishing ltd. 2001.

MSS productivity or its flow of sputtered atoms of a cathode-target material in time unit deposited on a substrate depends on bombarding ions current density and their energy. Ion flow to a cathode-target is proportional to a discharge current, which is one of main technological parameters that regulates a cathode-target sputtering rate. Another parameter is a mean ion energy Eᵢ determining a target's material sputtering coefficient that is proportional to a discharge voltage V_{d} and usually is estimated as Eᵢ˜(0.7−0.95)·eV_{d}, as described by D. Czekaj, E. K. Hollmann, A. B. Kozirev, et al. in, “Ion Energies at the Cathode of the DC Planar Magnetron Sputtering Discharge”, Journal of Applied Physics, A 49, 269-272, 1989, and by M. J. Goeckner, J. A. Goree, T. E. Sheridan, Jr., in “Monte Carlo Simulation of Ions in a Magnetron Plasma”, IEEE Transactions on Plasma Science, vol. 19, No. 2, 1991, where Eᵢ is a mean ion beam energy, e is an electron charge, V_{d} is a discharge voltage. Regulating a discharge voltage, one can change energy of ions and, therefore, a target's sputtering coefficient. It is necessary to note that a MSS is characterized by a nonlinear dependence of a discharge voltage on a current, according to which a discharge voltage rate is decreased with a discharge current increase, as it is described in “Thin Film Processes”, edited by J. L. Vossen and K. Werner, Academic, London, 1978. Because of this nonlinear dependence, MSSs, as a rule, are utilized in a range of discharge currents, in which voltage does not change significantly, and one can assume that a discharge current regulation produces weak impact on energy of ions.

Increase of current in magnetron sputtering systems with purpose of improvement of productivity in many cases is not justified, because it leads to increase of a plasma density in a discharge area, and as a consequence, to increase of additional radiation and corpuscular impact on substrates with depositing films that can influence on properties of deposited films as it was described by J. R. Kahn, H. R. Kaufman, V. V. Zhurin, in “Substrate Heating Using Several Configurations of an End-Hall Ion Source”, Proceedings of 43^{rd} Annual Technical Conference of Society of Vacuum Coaters, Denver, Apr. 15, 2000, p. 621.

In DC-pulsed magnetrons there is additional limit for a discharge current's growth caused by conditions for development of arcs on a cathode surface. A reason is that a critical time necessary for an electric charge accumulation on non-electrically conducting (oxidized) cathode parts is inversely proportional to a discharge current, as described by S. Schiller, K. Goedicke et al., in “Pulsed Magnetron Sputter Technology”, Surface Coating Technology, 1993, v. 61, p. 331-337. That is why a pulse's current increase leads to necessity to reduce a pulse duration (increase of frequency), and also to reduce a duty cycle coefficient as described by A. Belkind, Z. Zhao, D. Carter, et. al. in “Pulsed-DC Reactive Sputtering of Dielectrics: Pulsing Parameter Effects”, Proceedings of 43^{rd} Annual Technical Conference of Society of Vacuum Coaters, Denver—Apr. 15, 2000, p. 86, which is required for neutralization of accumulated electric charge. Such situation, first of all, applies specific technical requirements for power supplies, and, then, increase of productivity due to increase of a discharge current in a pulse can be insufficient due to a reduced duty cycle coefficient, i.e. a magnetron's operation effective time.

It is also necessary to note, as it was described by R. Behrisch, W. Eckstein in “Sputtering By Particle Bombardment: Experiments and Computer Calculations From Threshold to MeV Energies.”, Springer, 2007, that the MSS operating voltages, determining energy of ions bombarding cathode, often correspond to parts of a non-linear growth of the sputtering coefficients as function of energy. In such cases, a discharge current increase for improvement of productivity is less effective in comparison with increase of a discharge voltage (energy) with the same powers applied into discharge.

Therefore, in the cases mentioned above, a preferable way for improvement of a MSS productivity is increase of energy of bombarding ions with a high discharge voltage. Increase of a discharge voltage at a fixed discharge current can be realized, as a most simple way by change of a magnetic field induction or pressure of a plasma creating working gas. However, a range of regulation of a discharge voltage, as described in detail in “Thin Film Processes”, edited by J. L. Vossen and K. Werner. Academic, London, 1978, does not exceed several hundred volts, which can be insufficient for substantial increase of the sputtering coefficients, especially for hardly sputtered materials. Besides this, in the magnetrons of majority of typical schemes with magnetic systems utilizing permanent magnets, as a rule, there are no possibilities for regulation of magnetic field. Another parameter—pressure of a plasma creating working gas, also quite frequently is not changed substantially due to operating limits of a working gas, because, first of all, it is necessary to provide a MSS stable operation (without discharge extinguishing), and second, there are always specific requirements for formation of deposited films, because with a pressure growth there is observed increase of collisions of sputtered atoms with a working gas. In result, there is observed a reduced mean energy of atoms coming to a substrate that influences significantly mechanism of formation and structure of deposited thin films as described by B. A. Movchan, A. V. Demchishin, “Obtaining Depositions During Vacuum Condensation of Metals and Alloys”, Soviet Journal Fizika Metetallov i Metallovedenie (Physics of Metals and Research) v 28, 1969, p 653, and by K. H. Guenther, “Revisiting Structure-Zone Models for Thin-Film Growth”, Proc. SPIE (International Society for Optics and Photonics), v 1354, 1990, 2.

In majority of industrial MSS there are utilized solid targets made of pure materials, alloys, or compact powders. A ratio of components deposited in thin films usually close to their ratios in targets. In some cases, when preparation of a multi-component target of required composition is impossible, or is too expensive, or material of such target has physical-chemical properties making its utilization as a magnetron's cathode difficult (for example, material with low electric conductivity), a thin film deposition of a required composition can be done with several magnetrons simultaneously sputtering different components. A necessary stoichiometry of components in a thin film is determined by ratio of discharge currents in magnetrons. However, a substantial shortcoming of this method is a stoichiometry non-uniformity of deposition, usually, along a magnetron's cathode length due to different placement of sources of sputtered components—independent MSSs.

A MSS with composite (mosaic) cathode, which all parts are in magnetic field formed by one magnetic system suggested in U.S. Pat. No. 4,505,798, K. Ramachandran et al “Magnetron Sputtering Apparatus”, March 1985, makes possible to achieve high uniformity of deposited thin films, because, in this case, sources of different sputtering components are substantially closer to each other, and, as a rule, placed in a necessary order. Shortcoming of a mosaic cathode is in absence of flexibility of a stoichiometry regulation of components in a thin film, because it is determined by only a ratio of areas of corresponding cathode parts with account for the sputtering coefficient of their materials.

A MSS scheme with a composite cathode can be also successfully utilized for fabrication of multi-layer depositions, as it was suggested, for example, in U.S. Pat. No. 4,488,956, “High-Power Cathode System for Producing Multilayers”, by M. Scherer at al., December 1984. Multilayer deposition is obtained due to successive substrate motion over cathode parts made of different materials. In this case, thicknesses of deposited layers at fixed speed of a substrate motion also are determined by ratio of areas of corresponding parts of cathode with account for the sputtering coefficients of different materials. For obtaining necessary ratios of deposited layers, in this case, it is required to make a new target with various ratios of areas of different cathode parts.

Thus, for production of multicomponent or multilayer depositions, it is necessary to develop new schemes of a MSS, which could simultaneously provide high uniformity of composition or ratio of thicknesses of obtained depositions and sufficient flexibility in regulation of these parameters.

### SUMMARY OF INVENTION

In light of the foregoing, it is an object of the invention is to provide a magnetron-apparatus with a cathode that presents a magnetron sputtering system with a cathode-target consisting of groups of segments, where each group is electrically insulated from each other. A group of segments (segment group) can consists of one or more segments. Cathode segments can be made of the same or different materials.

Another object of the invention is to provide a magnetron-apparatus with a non-equipotential cathode consisting of two, or more groups of segments, where the applied potential on at least one of them is different from other, or others. All segments in each separate group of segments have an equal potential.

Control over the total discharge current is realized by regulation of the current coming to a group or groups of segments that is at the minimum voltage relative to anode. This voltage is self-established and depends on the segment's applied current, on specific discharge conditions and a magnetron design. A group of segments under this lowest voltage referred as a LOW VOLTAGE group of segments.

Yet another object of the invention is a possibility of independent control of voltages higher than at low voltage group of segments, which are applied to another groups of cathode segments, which are referred as a HIGH VOLTAGE groups of segments.

Yet another object of the invention is a possibility of independent control of energies of sputtering ions arriving to a different high voltage groups of segments of a cathode target providing regulation of sputtered particles flows from different parts of cathode-target to control of a thickness distribution or/and stoichiometry of deposited films.

Another object of the invention is to provide an apparatus with a magnetron sputtering system that presents a method of a discharge voltage regulation and control of a MSS productivity without increasing a discharge current, without changing parameters of magnetic field and pressure.

Yet another object of the invention is to provide a magnetron-apparatus with a non-equipotential cathode that presents a magnetron sputtering system with a cathode-target consisting of groups of segments electrically insulated from each other, in which regulation of currents and voltages on all segments is provided by one or several Power Supplies.

Yet another object of the invention is to provide a magnetron-apparatus with a non-equipotential cathode that can be applied to the existing magnetron sputtering systems and can be adapted to the invented method.

### BRIEF DESCRIPTION OF FIGURES

Figures of the present invention that are believed to be patentable are set forth with particularity of appended claims. The organization and manner of operation of the invention, together with further objectives and advantages thereof, may be understood by reference of the following descriptions of specific embodiments taken in connection with accompanying drawings and figures in which:

FIG. 1 represents a scheme of magnetron of axial-symmetrical geometry with a non-equipotential plane cathode-target consisting of two segments: low voltage LV and high voltage HV provided by two independent power supplies PS1 and PS2.

FIG. 2 represents a variation of discharge current densities as function of discharge voltages in a magnetron discharge in an equipotential regime of magnetron operation for fixed values of a discharge current. Also, in a FIG. 2 there are presented experimental points for low-voltage and high-voltage magnetron segments obtained during increasing of electric potential on a high-voltage segment with preservation of the same fixed value of a total current as in equipotential regime.

FIG. 3 represents a scheme of a graphite sputtering by a Magnetron Sputtering System with equipotential and non-equipotential cathodes modes provided with an external switch from one power supply PS.

In FIG. 4 there is presented a magnetron scheme with 4 groups of segments. PS1 and PS2 are power supplies, R is a resistive ballast, ER is electronic equivalent of resistive ballast. Voltage of a group of segments made of different materials is applied directly (group 1, or group 3) through a resistive ballast (group 2) and an electronic equivalent of ballast resistor (group consisting of one segment—segment 4). In assumption that a group of segments 1 made of material M1 operates as a low-voltage (i.e. it is on lowest applied voltage among all four groups of segments), and a higher voltage is on a group 2 also made of material M1, it improves a space uniformity of sputtering and reduces boundary effects. Stoichiometric ratio of components in deposition and its uniformity is determined by the voltages on the groups 3 and 4 made of material M2. Also, for providing a stoichiometric uniformity the segments of different materials are alternated.

FIG. 5 depicts a Volt-Ampere Characteristic with a planar Magnetron Sputtering System with equipotential and non-equipotential cathodes in Argon media with pressure P=0.5 Pa.

FIG. 6 depicts distribution of a deposited graphite on a substrate in a Magnetron Sputtering System with equipotential (operating point 1 EQUI) in FIG. 5 and non-equipotential cathodes (operating point 2 NON-EQUI) in FIG. 5.

FIG. 7a, FIG. 7b and FIG. 7c represent a variation of discharge current densities as function of discharge voltages in a magnetron discharge with a non-equipotential cathode for working gases: Nitrogen, Xenon and Oxygen.

### DESCRIPTION OF THE PREFERRED EMBODIMENTS

The invented Magnetron Sputtering System (MSS) has a cathode-target consisting of groups of segments, where each group is electrically insulated from others. In discharge over the whole cathode segments there is developed plasma with a drift of magnetized electrons. In this case, at least on one segment group, called further as LOW-VOLTAGE, or LV, of a cathode-target there is maintained an electric voltage relative to anode lower in comparison with a potential differences between anode and remaining groups of segments of a cathode-target, called further as HIGH-VOLTAGE, or HV. Such system called as MSS with a NON-EQUIPOTENTIAL CATHODE (NEC). Together with a term LV or HV for a group of segments there is utilized in a patent's text a term LV or HV for segments, if a corresponding group consists of one segment.

Voltage on the LV group or groups of cathode segments of the invented Magnetron Sputtering System is self-established and depends mainly on the segment's applied current, on a composition and pressure of a plasma developing working gas, on cathode segments materials, on magnetic field parameters and on a magnetron design. Control over the total discharge current in the invented Magnetron Sputtering System is realized by regulation of the current coming to a low voltage group or groups of cathode segments.

Voltages on the EIV groups of cathode segments of the invented Magnetron Sputtering System do not depend on current densities on the segments. These voltages can be regulated independently from each other and from a voltage on the LV group of segments.

The invented Magnetron Sputtering System and the method of a discharge voltage regulation allow controlling a MSS productivity without increasing a discharge current and without changes of magnetic field and pressure parameters. Also, this method gives a possibility for independent control of energies of sputtering ions coming to different groups of cathode segments which can be made of the same or different materials, allowing the flows of sputtering particles regulation from separate parts of a cathode-target.

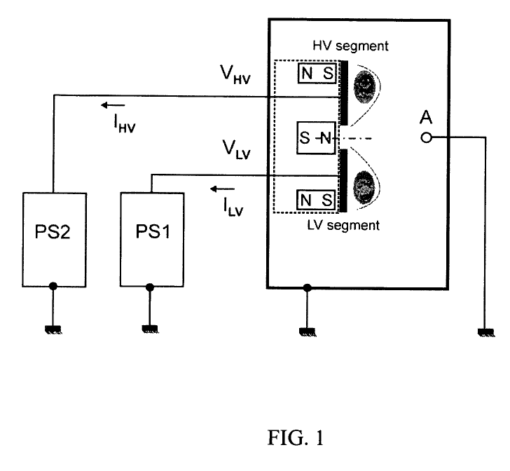

In FIG. 1 there is presented an example of a scheme of magnetron of an axial-symmetrical geometry with a non-equipotential plane cathode-target consisting of two segments—low-voltage, LV and high-voltage, HV. The discharge voltage V_{LV} between segment LV and anode A is maintained by a power supply PS1. The discharge voltage V_{HV} between segment HV and anode A is maintained by a power supply PS2. The discharge voltage V_{HV} is higher than V_{LV}, or V_{HV}>V_{LV}.

According to our experimental data, the current density coming to a high-voltage segment of a cathode-target is determined by the current density at its low-voltage segment and is calculated from the condition of approximate equality of a current density at both cathode segments I_{HV}/S_{HV}=I_{LV}/S_{LV}, that gives: I_{HV}=I_{LV}S_{HV}/S_{LV}, where S_{HV} and S_{LV} are areas of erosion zones (sputtering areas) on corresponding segments. In a cathode low-voltage segment a current and voltage are interconnected parameters characterized by a Volt-Ampere Characteristic (VAC) of a low-voltage segment. In general, this VAC (dependence of a current density on voltage) is close to a Volt-Ampere Characteristic of the same magnetron operating in the scheme with an equipotential cathode. At the same time, in the cathode-target's high-voltage segment discharge voltages do not depend on a current density and are easily regulated. According to our experiments, the maximum potential difference between high-voltage and low-voltage parts (segments) is limited only by the dielectric strength of insulating gap between these parts.

In FIG. 1 the magnetron's total discharge current that consists of currents coming to the cathode low-voltage and high-voltage segments is controlled by a current in circuit of a low-voltage element. Average current densities on high-voltage and low-voltage cathode parts in most cases are not equal, though are close to each other. The difference of current densities of high-voltage and low-voltage segments depends mainly on ratio of area occupied by a low-voltage part to a total cathode area, on a total current applied to a cathode-target, on pressure of a plasma developing working gas, and also on the parameters of a magnetic field over a cathode-target surface.

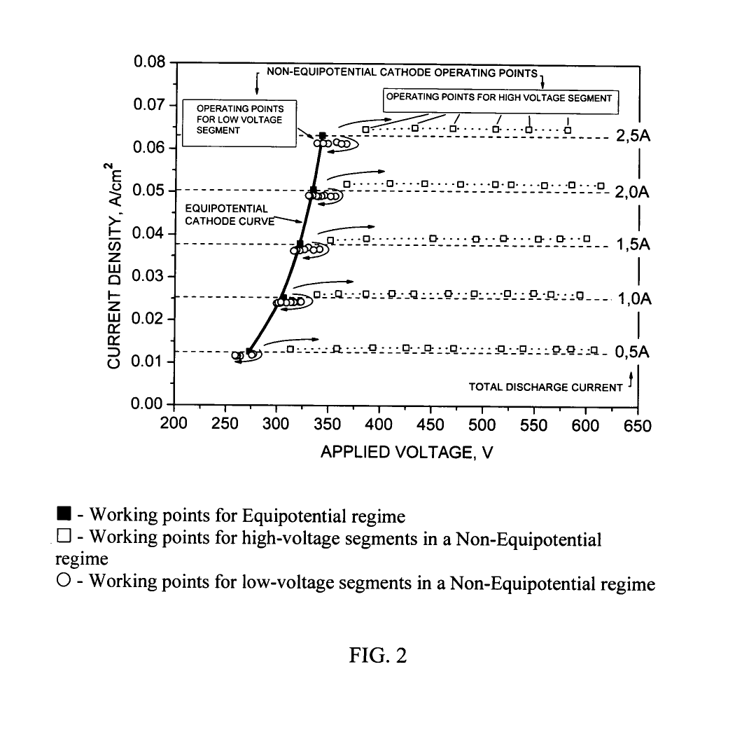

In FIG. 2 there are presented the general VAC dependencies of a discharge current density as function of voltage in Argon media for axial-symmetrical magnetron of 2″ diameter made of Aluminum with an equipotential and a non-equipotential cathode regimes of operation. Cathode was prepared of two parts with equal areas, on which in correspondence with FIG. 1, there were applied the electric potentials from two power supplies.

Experimental procedure of obtaining the VAC dependencies shown in FIG. 2 was as follows. For five different values of a discharge current to a cathode I_{d}=0.5 A, 1.0 A, 1.5 A, 2.0 A, 2.5 A there were provided independent cycles of measurements. At the beginning of each cycle on both segments of a cathode there was applied the same voltage from power supplies PS1 and PS2 corresponding to a selected value of a total current determined as a sum of currents of power supplies PS1 and PS2. Thus, there was defined a working point of an equipotential regime of a magnetron operation. Then a voltage from a power supply PS2 on a HV segment was increasing in comparison with a voltage on a power supply PS1 providing voltage for a LV segment, which corresponds to transition in to a regime with a non-equipotential cathode. In this case, a total value of a whole current was maintained at a constant level by only a current's regulation in a low-voltage circuit with a PS1. During increasing of the HV segment voltages the operating points for a low-voltage segment grouped near the working point corresponding to an equipotential regime. Also, in this case, the current densities on a high-voltage segment remained approximately constant and close to the current density for an equipotential regime.

Similar experiments were conducted with other ratios of the high-voltage and low-voltage areas and with various working gases. The minimum portion of a low-voltage area from a total cathode area was ⅙. In all cases, the magnetron demonstrated stable operation in accordance with the above described principles with similar behavior of discharge parameters with increase of voltage on a high-voltage part. Also, there was found that the operation points on the low-voltage elements were grouped closer to the equipotential operating point, if the portion of a cathode-target of a low-voltage part area to its total area is increased. It is necessary to note about the fact of a stable magnetron operation with NEC with area of a low-voltage element lower than 20% of a cathode total area, which is very important factor for increasing the total MSS productivity. It is crucial that the area of the cathode-target high-voltage segment substantially exceeded the area of the low-energy segments.

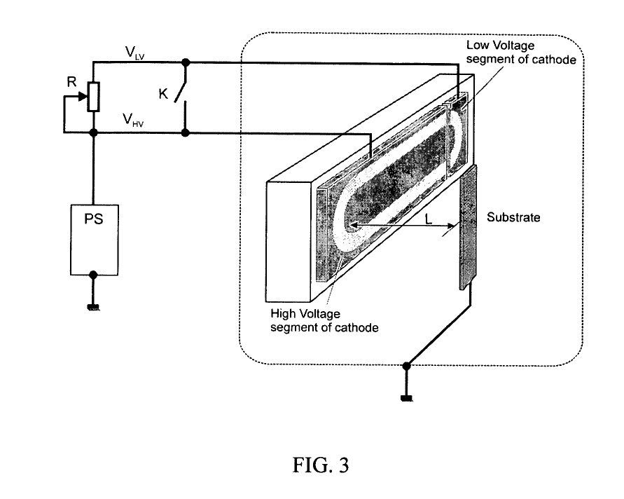

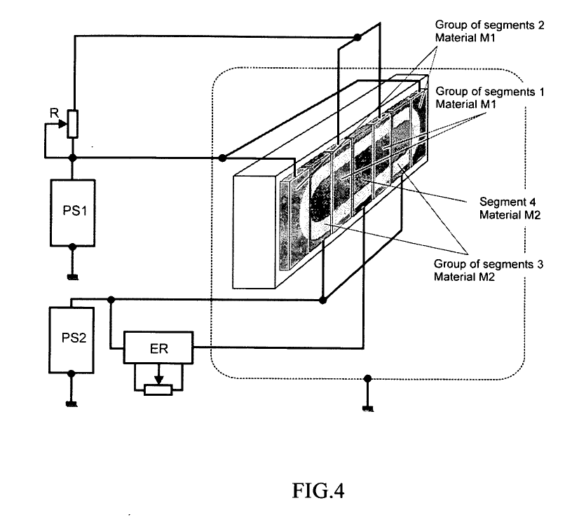

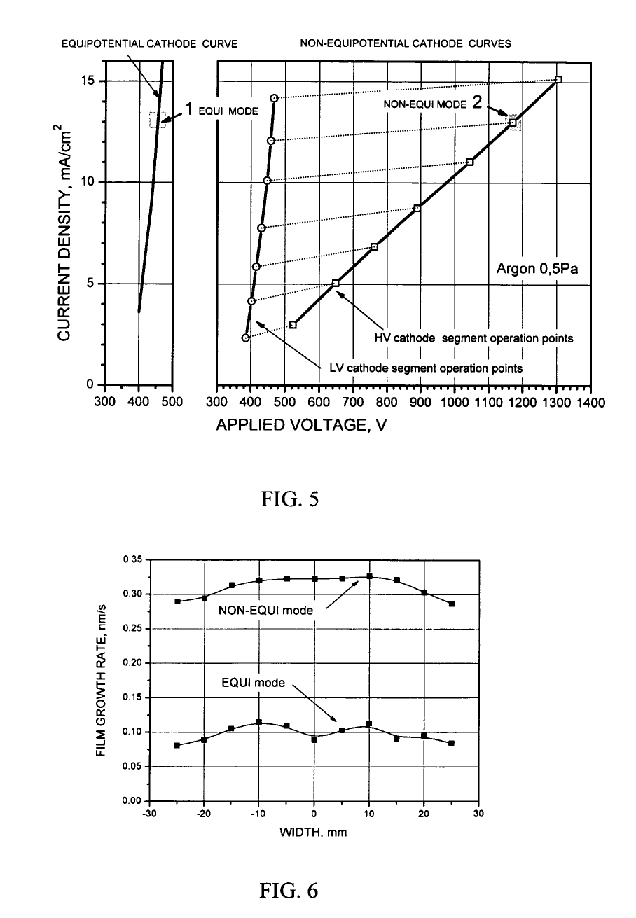

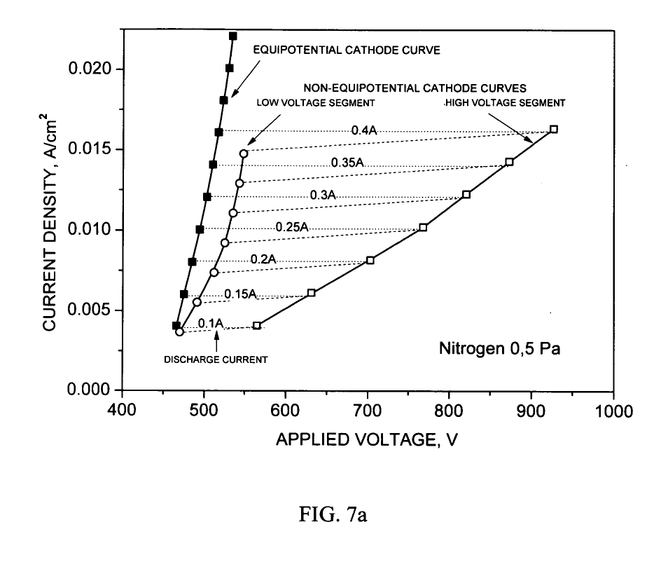

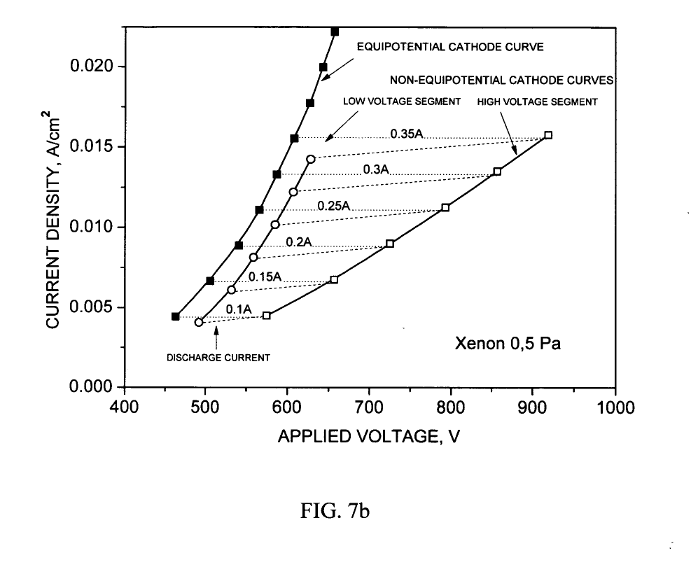

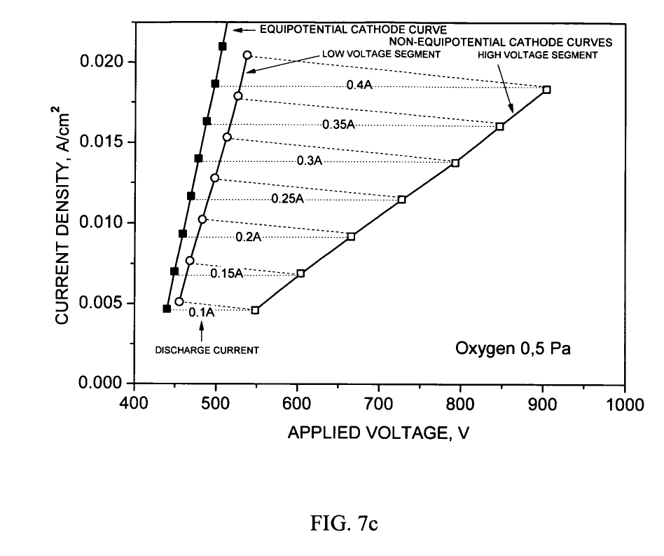

Electric power supply for different cathode parts can be arranged as with utilization of independent power supplies (FIG. 1), as from one power supply with utilization of ballast elements (FIG. 3) for organization of the power supply of cathode segments that are at lower voltage relative to anode in comparison with one power supply.

An example of a scheme of applied power with one Power Supply PS is given in FIG. 3 where a ballast resistor R is utilized. With such a scheme of a power supply on a cathode low-voltage segment there is a self-established electric potential close to electric potential that regularly exists on an equipotential cathode with the same current density. A potential difference between the high-voltage and low-voltage cathode parts falls on a ballast resistor R. The ballast resistor value R can be selected in such a way that at a given magnetron current I the voltage drop between the low and high-voltage segments has to be equal to a value: V_{HV}−V_{LV}=R·I_{LV}≈R·I·S_{LV}/(S_{HV}+S_{LV}), where I_{LV} is a current on a low-voltage segment, S_{HV}/and S_{LV} are sputtering areas on high voltage and low-voltage segments, respectively. Here the experimental fact that current densities on the low and high-voltage segments are usually close to each other is taken into account. Therefore a part of a segment discharge current of a total discharge current is approximately equal to a part of the segment's sputtering area of a total sputtering area of a cathode. This procedure allows obtaining the voltage drop between the high and low-voltage cathode segments that depends on the total current only. In this case, the potential on a low-voltage cathode segment is usually close to an equipotential cathode potential at the same current density.

Instead of a ballast resistor R for maintaining current and voltage on the low-voltage segments its electronic equivalent based on linear regulators or switching schemes can be utilized, and that was done in our experiments. An electronic equivalent of a ballast resistor maintained the current and corresponding to it voltage on a cathode's low-voltage segment independently of voltage on a high-voltage segment. In case, if necessary to maintain more than two different voltages on the cathode segments, there could be utilized several resistive ballasts or its electronic equivalent in the corresponding segment's circuits. FIG. 4 demonstrates the examples of ways of a power supply realization to the non-equipotential cathode. In this case, the current to a LV group of segments (marked at FIG. 4 as a segment group 1) is supplied by PS1 through a resistive ballast R and as a result a voltage on the LV-group of segments self-establishes close to the equipotential cathode but the voltages on the other segments can be regulated with the electronic equivalent of ballast or separate power supplies. The current to a HV group of segments (marked at FIG. 4 as a segment group 2) is supplied by PS2 through an electronic ballast ER.

It is experimentally confirmed that with increase of voltage on cathode-target high-voltage segments the total productivity of the system increases. As example, let us consider two experiments of a thin film deposition in a planar expanded MSS with the cathode-target dimensions of 2″×5″made of a hardly sputtered material—graphite (Carbon). These experiments were carried out according to a scheme presented in FIG. 3. Magnetron sputtering was conducted in Argon media with pressure of 0.5 Pa. Magnetic induction on the center of erosion zone on the MSS cathode surface was about 0.1 TI. In the first experiment, cathode was connected according to an equipotential scheme; in the second experiment, cathode was a non-equipotential consisting of two parts: low-voltage LV and high-voltage HV. The area of a NEC low-voltage part was 18% of its total area. The current density to a high-voltage cathode part in the second experiment (NEC) was equal to the average current density in the first experiment (EC). In both experiments, a substrate was at distance L=45 mm, in the same place relative to a cathode surface. Power to all cathode parts in the second experiment was provided from one power supply. An electric potential to a low-voltage cathode part was applied through a ballast resistor R in a PS circuit. Switching between the regimes between EC and NEC was realized by a simple shunting of a ballast resistor R by a commutator K (switch on-off).

In FIG. 5 there are presented the Volt-Ampere Characteristics (VAC) of the magnetron shown in FIG. 3 for both experiments: for the equipotential EC and non-equipotential cathodes NEC, correspondingly. For the case with a NEC, these VAC dependencies are presented separately for a high-voltage (high-voltage curve) and a low-voltage (low-voltage curve) cathode segments. Only one operating point of a low-voltage curve corresponds to each high-voltage curve (the voltage differences between corresponding operation points are equal to voltage drops at ballast resistor with value R). In FIG. 5 corresponding points are connected by dashed lines.

In the experiment with EC, a current density for a magnetron operating point marked as EQUI MODE 1 on FIG. 5 was 13 mA/cm² at a discharge voltage of 450 V. In the experiment with a NEC, a current density on a low-voltage cathode segment was 12 mA/cm² at a discharge voltage of 460 V and on a high voltage cathode segment 13 mA/cm² at a discharge voltage of 1180 V, where this operating point on FIG. 5 marked as NON-EQUI MODE 2.

Productivity of the system in the above described experiments was estimated by measuring thickness of films deposited in EQUI MODE 1 and NON-EQUI MODE 2 during the same time periods on a substrate placed across a magnetron's longitudinal axis at distance of L=45 mm from a cathode surface. In this case, a certain substrate's part was masked. The deposited layers thicknesses were measured by a profilometer. Experimental results showed that a thin film deposition thickness in the experiment with NEC was in average higher in three times in comparison with a thin film deposited with EC. In FIG. 6 there are presented experimental results of both experiments.

Observed increase of a MSS productivity with a NEC is explained by the increased sputtering coefficient in about three times, 3:1, caused by a corresponding increase of the mean energy of ions bombarding cathode. This is in a good agreement with data on a graphite sputtering by Argon ions at energies of 1100 eV and 400 eV, which is about, 2.1:1, according to R. Behrisch, W. Eckstein, “Sputtering by Particle Bombardment: Experiments and Computer Calculations from Threshold to MeV Energies”, Springer, 2007, and is about 3.4:1, according to data from modeling program SRIM, by J. Biersack, Ziegler J. P., Ziegler M. D. “SRIM—The Stopping and Range of Ions in Matter”, Lulu Press Co., 2008.

It was confirmed experimentally that utilization of magnetron with a non-equipotential cathode is possible in media of majority utilized in industry plasma developing gases. The experiments were carried out according to a scheme with a ballast resistor shown in FIG. 3 with a magnetron having cathode made of graphite with dimensions of 2″×5″. An area of a low-voltage NEC segment was 18% from total area of cathode. In FIGS. 7a, 7b and 7c there are presented the discharge current density dependencies of voltage for the low-voltage and high-voltage segments of cathode obtained in experiments with Nitrogen at pressure 0.5 Pa, with Xenon at pressure 0.5 Pa and with Oxygen with pressure 0.5 Pa. All tested working gases have similar tendencies that a current density at a low-voltage segment is slightly lower by few percents than a high-voltage segment. This tendency is different for Oxygen: its current density at a low-voltage segment is slightly higher by few percents than at a high-voltage segment. This is a result of changing conditions at a high-voltage segment at its cathode layer, and is explained by intensive development of carbon oxides CO and CO₂.

Scheme of Magnetron Sputtering System with the non-equipotential cathode allows to increase substantially (in several times) an electric voltage on the high-voltage segments of a cathode-target in comparison with electric voltages characteristic for the equipotential cathode. In this case, the area occupied by the cathode high-voltage segments can substantially exceed the area of the low-voltage segments. The productivity increase of a MSS is provided by the sputtering coefficient growth for the most part (high voltage part) of a cathode-target. In application of MSS with a NEC for sputtering materials, which sputtering coefficients increase non-linearly with increase of ion energy, the increase of the productivity exceeds the productivity increase due to a growth of electric current in MSS of the traditional schemes at equal applied electric powers. Utilization of MSS with a NEC allows substantially increasing the sputtering system productivity without change of discharge current, because the discharge voltages at the high-voltage groups of segments do not depend on discharge currents at them. Scheme of MSS with a NEC can be utilized for control of the local productivity of a cathode-target allowing a flexible control over the deposition in the substrate's various parts.

The invented method allows not only to increase and control magnetron productivity, which means a possibility of independent regulation of flows of sputtered particles from the cathode's separate parts. For this purpose, the non-equipotential cathode-target must consist of segment groups, each of which is maintained in discharge at certain potential depending on the sputtering coefficient determining required local productivity. The group of segments, from which flow of sputtered atoms must be at minimum, is the low-voltage segment group of the non-equipotential cathode-target; the other cathode groups of segments must be at higher voltage. The similar method can be utilized for obtaining a given distribution of deposited thin film thicknesses with the long planar magnetrons, in particular, for equalization of thickness of a thin film deposited layer. For example, in a long planar magnetron with EC, the thickness of a thin film deposited layer is at maximum over the magnetron's central part and it decreases to magnetron's edges. If one would utilize magnetron with a NEC, in which the peripheral parts are at high voltage, then the indicated deposition non-uniformity can be reduced significantly. It is necessary to note that electric potentials on the cathode high-voltage parts can be regulated from thicknesses of deposited layers measured by probes placed in the control points that make possible to regulate a deposited layer profile.

The invented non-equipotential cathode of a suggested MSS can consist of segments made of various materials. In magnetrons with the equipotential cathodes, which sections prepared of various materials, the stoichiometry of depositions depends on the ratio of areas of sections and the magnetic field configuration determining the geometry of a target sputtering area. Utilization of the scheme with a NEC in this case gives additional advantage making possible to provide flexible control of the deposition's stoichiometry. According to this scheme, all cathode segments made of different materials must be on segment groups electrically insulated from each other. Electric voltages of the cathode-target segments made of different materials consisting of components which are supposed to be regulated in a deposited film must be higher than the low-voltage group of segments voltage. Electric potentials of the NEC high-voltage segments must be selected according to the materials sputtering coefficients dependence on ion energies (discharge voltages) and according to the required local composition (stoichiometry) and thickness of deposited film. Electric potentials on the high-voltage NEC segments can be changed during the technological process, making possible to control a stoichiometry depth profile. For obtaining flows of sputtered particles with uniform ratio of components in a flow, the non-equipotential cathodes can be utilized, which the low-voltage segment group and high-voltage segment groups consist of several segments uniformly distributed over the cathode surface and having the same electric potentials—correspondingly, at low and high voltages.

Which group of segments will be a low-voltage, in general, will depend on the designed stoichiometry of deposition and on the sputtering coefficients of sputtered materials. The condition for the designed stoichiometry can be expressed by formulas (here is N−1 formula):

γ₁S₁/k₁=γ₂S₂/k₂= . . . γ_{N}S_{N}/k_{N}

where kᵢ is a stoichiometry coefficient of i-th component of a deposit, γᵢ is a sputtering coefficient of i-th material of the mosaic-type cathode segments corresponding to i-th component of a deposit, Sᵢ is the total sputtering area of all segments made of i-th material in a mosaic-type cathode. Here it is assumed that i-th component of a deposit includes all deposited particles sputtered from cathode segments made of i-th material, N is a number of materials of cathode segments. Realization of the above mentioned condition allows to fabricate deposited film with required composition and to achieve uniform sputtering of mosaic-type cathode-target. The potential difference applied to an i-th group of segments of non-equipotential cathode is the higher, the smaller a product γᵢSᵢ/kᵢ for the group of segments in the equipotential cathode condition, which, as a rule, is a characteristic for materials with a low sputtering coefficient γᵢ. In most cases, segments made of material with the high sputtering coefficient will be in the low-voltage group of segments. For example, for a composition Ti—C the low-voltage segments will be made of Titanium, because Carbon has quite low sputtering coefficient. The required stoichiometry can be provided through selection of various segments areas ratios. A large difference between areas of the segments made of different materials can lead to a significant stoichiometric nonuniformity along a deposited film. Therefore, if the ratios γᵢ/kᵢ differ significantly, this will be not a reasonable solution. In this case, it is preferable to decrease γᵢ/kᵢ differences by regulating energies of bombarding ions coming into the segments. Operation of a mosaic cathode by the NEC scheme makes possible to solve this problem. It has to be noted that in the process of sputtering of the mosaic cathode the sputtering coefficients of various segments can be changed in time due to redeposition of atoms of sputtered segments made of different materials. The NEC scheme allows very flexible regulation of the stoichiometry even in this case.

Scheme of MSS with a NEC can be effectively utilized for regulation of stoichiometry of deposition obtained during sputtering of a cathode-target consisting of different materials. The contents of regulated components in different parts and various depths of deposited materials are determined by the variation of electric potentials on the high-voltage parts of the magnetron's cathode-target.

During utilization of magnetron with NEC a rate of cathode segments erosion in general case will be not the same due to their different sputtering coefficients and because of different applied voltages; and also, in case of a mosaic cathode, because of different materials of segments. One of possible ways for compensation of accelerated wear out of some segments relative to the others is their mutual movement in a vertical direction providing the same height of their maximum points of sputtering (equalization of a depth of segments erosion). Such motion of cathode segments can be provided as in time periods between the operations, as during the technological process to secure stability of magnetron's discharge parameters.

Another possible method for equalization of an erosion depth of the non-equipotential cathode segments made of the same material is alternative change of potentials applied to different groups of segments in certain time intervals. In result, the low-voltage groups of segments become as the high-voltage parts of cathode. On the average, this provides a uniform wear out of the cathode. Total performance of magnetron with a non-equipotential cathode utilized in such way will exceed its output in case of an equipotential cathode, because in a NEC there will be always some segment groups (current high-voltage groups of segments) operating at high voltages.

Another possible method of equalization of the segments erosion depth is a local change of configuration, and/or an amplitude of a magnetic field induction (local profiling of magnetic field) with purpose of local change of the erosion area width on the certain cathode segments. Local variation of configuration and induction of magnetic field can be performed with change of the inter-poles distances at parts of magnetic system placed under certain segments of a cathode-target, or by variation of induction of some elements of a magnetic system. In particular, in order to provide equalization of depth of a target's erosion the inter-poles gap under the high-voltage segments can be made wider than under the low-voltage segments. Another way of a local magnetic field profiling for equalization of the target's erosion depth is a local movement of the magnetic system elements, or change of induction of some elements of the magnetic system with purpose to move the erosion area in one, or another side from initial position (change of geometry of a sputtering path) for some high-voltage segments. Both types of the local magnetic field profiling can be done as between the technological processes (by restructuring the magnetic system), as during the technological process.

The non-equipotential cathode-target can be successfully utilized in DC-pulsed magnetrons (unipolar and bipolar). In this case, the main principles of organization and control of discharge in a DC-pulsed magnetron with a non-equipotential cathode are completely similar to a DC-magnetron with NEC. Power supplying is provided by synchronous pulses of voltage with the same frequency and duration for all groups of segments of a non-equipotential cathode-target. The minimum amplitude voltage is applied to the low-voltage groups of segments; on the other groups of segments the voltage amplitudes are higher and are freely regulated. Control over the discharge current is realized by regulation of the current in the low-voltage circuit, similar to a DC-magnetron with NEC. Possible schemes of power supplying for a DC-pulsed magnetron with a non-equipotential cathode are similar to a DC-magnetron with a NEC.

Utilization of a NEC in DC-pulsed magnetrons allows to increase their performance by increasing the sputtering coefficients of materials of the cathode-target segments through increasing the discharge voltage on high-voltage segments. It is remarkable and important that this growth of efficiency of output is achieved without increasing the discharge current density, and allows to avoid an increase of accumulated electrical charge during discharge on the cathode's surface, and, therefore, do not reduce the discharge duty cycle.

The non-equipotential cathode-target can be utilized in magnetrons with a non-balanced magnetic field and with the closed magnetic configurations. In both cases, the principles of discharge organization and control, and also the schemes of power supplying in such magnetrons with utilization of NEC are completely similar to above discussed.

In conclusion, a new Magnetron Sputtering System with a Non-Equipotential Cathode possesses the following new discovered physical features, such as:

1. In a Magnetron Sputtering System with a Non-Equipotential Cathode, where a plasma cloud develops over all cathode segments, a low-voltage group/groups of segments provides control of discharge current to the whole cathode-target, consisting of low and high-voltage groups of segments.

2. In such a Magnetron Sputtering System with a Non-Equipotential Cathode it is possible to apply electric voltage (voltages relative to anode) to one or several segment groups of cathode much higher than it takes place with an equipotential cathode.

3. In such a Magnetron Sputtering System with a Non-Equipotential Cathode a creation of ionized plasma with drift of magnetized electrons is formed, and there are developed the conditions providing electrical insulation of various segments of a magnetron's cathode-target over its surface;

4. Magnetron Sputtering System with a Non-Equipotential Cathode makes possible to provide independent control of energies of sputtering ions coming to various parts of a cathode-target;

5. Magnetron Sputtering System with a Non-Equipotential Cathode makes possible significantly to increase a cathode-target sputtering rate on separate segments made of the same material, or of different materials;

6. Magnetron Sputtering System with a Non-Equipotential Cathode makes possible to provide control of stoichiometry of deposited films obtained during sputtering of a cathode-target consisting of different materials;

7. Magnetron Sputtering System with a Non-Equipotential Cathode makes possible to provide a uniform sputtering of various parts of a cathode-target which made of one or different materials with various sputtering coefficients.

8. Magnetron Sputtering System with a Non-Equipotential Cathode makes possible to provide control of deposition distribution thicknesses over the deposition area, and, as a particular case, with high uniformity.

We claim:

1. A magnetron-apparatus with a Non-Equipotential Cathode that presents a Magnetron Sputtering System. This magnetron-apparatus of a coaxial or planar geometry operating either with a DC current, or with a pulsed unipolar, or bipolar regime, in which there is developed a self-sustained magnetron plasma discharge in practically all industrial utilized working gases, such as Argon, Oxygen, Nitrogen, Xenon, and others including but not limited to hydrocarbons, when working gases in discharge have ionized plasma with drifted in crossed electric and magnetic field magnetized electrons. A magnetic field configuration in such a magnetron can be both a balanced and unbalanced. This Magnetron Sputtering System comprising the following features:
(a) a cathode-target consisting of groups of segments, where each group is electrically insulated from others; each group of segments can consist of one or more segments of the cathode-target; this magnetron-apparatus operates with a formed creation of ionized plasma with drift of magnetized electrons developed over all cathode segments, where the plasma creation with cathode sheath does not lead to electrical short of various isolated groups of segments of a magnetron's cathode-target;
(b) providing that at least one group of segments that is at lowest discharge voltage than other groups of segments, and this voltage is a self-establishing one;
(c) providing that a discharge current density at whole cathode is determined by a current density at the lowest voltage group or groups of segments of a cathode (low-voltage group or groups of segments);
(d) providing that in the discharge conditions voltages at groups of segments of a magnetron's Non-Equipotential Cathode, which are higher then at low-voltage group or groups of segments, do not depend on current densities and can be controlled independently;
(e) a creation of ionized plasma allows maintaining an electric potential over each cathode segment without impact on neighbor segments that allows regulation of each group of segments electric potential and regulation of corresponding ions mean energy over the group of the segments.

2. A method for providing a Magnetron Sputtering System described in claim 1 and comprising the steps of:
(a) providing that a Non-Equipotential Cathode allows regulation of productivity of a magnetron system without increasing a discharge current and without changing a magnetic field and pressure of a system;
(b) providing that during Magnetron Sputtering System operation it is possible to regulate a thickness distribution of a deposited film over the deposition area, in particular, for equalization of thickness of a deposited film;
(c) providing that segments of a cathode-target can be made of different materials;
(d) providing that a Non-Equipotential Cathode where segment's materials at least in one group of segments are different from segment's materials in other groups of segments allows regulation of a stoichiometry of deposited layers during a Magnetron Sputtering System operation;
(e) providing that the voltage conditions on the groups of segments can be changed during operation, in particular, one, or other high-voltage group of segments can become as a low-voltage group of segments for a uniform sputtering of a cathode-target;
(f) providing that it is possible to compensate excessive erosion of a high-voltage segments and equalize erosion depth on segments by local profiling of a magnetron magnetic field and/or movement the segments in a vertical direction as before and during a Magnetron Sputtering System operation.

3. Apparatus for providing a Magnetron Sputtering System with a Non-Equipotential Cathode defined in claim 1, and 2, further comprising:
(a) providing that a discharge current and voltage in a low-voltage and high-voltage groups of segments are supplied with separate Power Supplies for each segment groups at the same potential;
(b) providing that a discharge current and voltage in a low-voltage and high-voltage groups of segments, instead of separate Power Supplies, are operated with one Power Supply through either a resistive ballast or its regulated electronic equivalent;
(c) providing that a discharge current and voltage in a low-voltage and high-voltage some groups of segments have electric potentials from several Power Supplies and other segments through resistive ballasts or its regulated electronic equivalents;
(d) providing a stable operation of magnetron with a Non-Equipotential Cathode, where the total area of a high-voltage group or groups of segments up to 10 times exceeds the total area of a low-voltage group or groups of segments.
